(19) United States
(12) Patent Application Publication
(10) Pub. No.: US 2022/0137396 A1
(43) Pub. Date: May 5, 2022

(54) ATTACHMENT FOR REDUCING TEMPERATURE SENSITIVITY

(71) Applicant: Beijing Voyager Technology Co., Ltd., Beijing (CN)

(72) Inventors: Sae Won Lee, Mountain View, CA (US); Youmin Wang, Mountain View, CA (US); Yue Lu, Mountain View, CA (US); Gary Li, Mountain View, CA (US)

(21) Appl. No.: 17/089,434

(22) Filed: Nov. 4, 2020

(51) Int. Cl. G02B 26/08; G01S 17/931; G01S 17/08; G01S 7/481; B81B 7/00

(52) U.S. Cl. CPC G02B 26/0833; G01S 17/931; B81B 2201/042; G01S 7/481; B81B 7/008; G01S 17/08

(57) ABSTRACT

Embodiments provide a method and mechanism for reducing changes in the resonant frequency of a MEMS mirror structure with temperature due to a mismatch between the CTE of the MEMS die and the package substrate. A die attach layer with a low Young's modulus, such as less than 15,000 psi, is used to allow absorption of some of the stress due to the mismatch in the CTE of the MEMS die and the package substrate. In addition, in embodiments a thicker die attach layer than normal is used to absorb some of the stress, increasing the height of the die attach layer from the normal range around 25 μm to between 50-150 μm thick. In further embodiments a pattern of open cavities is etched in the bottom of the die substrate. The die substrate may be made thicker to provide room for the cavities.

### BACKGROUND OF THE INVENTION

Unless otherwise indicated herein, the materials described in this section are not prior art to the claims in this application and are not admitted to be prior art by inclusion in this section. In particular, disparate technologies are discussed that it would not be obvious to discuss together absent the teachings of the present invention.

Modern vehicles are often equipped with sensors designed to detect objects and landscape features around the vehicle in real-time to enable technologies such as lane change assistance, collision avoidance, and autonomous driving. Some commonly used sensors include image sensors (e.g., infrared or visible light cameras), acoustic sensors (e.g., ultrasonic parking sensors), radio detection and ranging (RADAR) sensors, magnetometers (e.g., passive sensing of large ferrous objects, such as trucks, cars, or rail cars), and light detection and ranging (LiDAR) sensors.

A LiDAR system typically uses a light source and a light detection system to estimate distances to environmental features (e.g., pedestrians, vehicles, structures, plants, etc.). For example, a LiDAR system may transmit a light beam (e.g., a pulsed laser beam) to illuminate a target and then measure the time it takes for the transmitted light beam to arrive at the target and then return to a receiver near the transmitter or at a known location. In some LiDAR systems, the light beam emitted by the light source may be steered across a two-dimensional or three-dimensional region of interest according to a scanning pattern, to generate a “point cloud” that includes a collection of data points corresponding to target points in the region of interest. The data points in the point cloud may be dynamically and continuously updated, and may be used to estimate, for example, a distance, dimension, location, and speed of an object relative to the LiDAR system.

Light steering typically involves the projection of light in a pre-determined direction to facilitate, for example, the detection and ranging of an object, the illumination and scanning of an object, or the like. Light steering can be used in many different fields of applications including, for example, autonomous vehicles, medical diagnostic devices, etc., and can be configured to perform both transmission and reception of light. For example, a light steering transmitter may include a micro-mirror to control the projection direction of light to detect/image an object. Moreover, a light steering receiver may also include a micro-mirror to select a direction of incident light to be detected by the receiver, to avoid detecting other unwanted signals. A micro-mirror assembly typically includes a micro-mirror and an actuator. In a micro-mirror assembly, a micro-mirror can be connected to a substrate via a connection structure (e.g., a torsion bar, a spring, etc.) to form a pivot point. One such type of micro-mirror assembly can be a micro-electro-mechanical system (MEMS)-type structure that may be used for a light detection and ranging (LiDAR) system in an autonomous vehicle, which can be configured for detecting objects and determining their corresponding distances from the vehicle. LiDAR systems typically work by illuminating a target with an optical pulse and measuring the characteristics of the reflected return signal. The return signal is typically captured as a point cloud. The width of the optical-pulse often ranges from a few nanoseconds to several microseconds.

Micro-mirror devices used in a LIDAR system can be designed to operate (scan) at a resonant frequency of the MEMS mirror structure for larger scanning angles. The resonant frequency can be controlled by the design of the MEMS mirror structure and the supporting torsion springs that support them. By operating at the resonant frequency, the mirror can more easily be rotated, with less power, since it tends to resonate or oscillate at that frequency. This allows the achievement of a large scanning angle with a low operating voltage. When the surrounding temperature changes, stress develops at the interface between the device and its package because of a mismatch in CTE (coefficient of thermal expansion) of the two materials. The tension within the torsion springs coupled to the suspended micro-mirror changes. This results in a shift of the micro-mirror's resonant frequency, and related system components need to adapt to the new frequency. In addition to frequency change, the tension between the micro-mirror and the package may also result in a bowed micro-mirror (ideally the micro-mirror or mirror array should be perfectly flat sitting on a silicon die substrate) and thus cause un-wanted light divergence. Accommodating for such temperature sensitivity can greatly increase the complexity of overall system.

Stress develops in the interface between the chip (die) and the package because of a mismatch in CTE (coefficient of thermal expansion) of the two materials. For example, a die could be mainly made of silicon and an enclosure could be a ceramic package which is made of alumina. The CTE of these two materials are different and they expand and contract at different rates with temperature. Alumina expands and contracts more than silicon, and thus stress develops at the interface of the two materials. This stress is transmitted to the devices in the substrate and can especially be noticeable in MEMS devices.

### BRIEF SUMMARY OF THE INVENTION

Embodiments provide a method and mechanism for reducing changes both in the resonant frequency and in flatness of a MEMS mirror structure with temperature due to a mismatch between the CTE of the MEMS die and the package substrate. A die attach layer with a low Young's modulus, such as less than 25,000 or less than 15,000 psi, is used to allow absorption of some of the stress due to the mismatch in the CTE of the MEMS die and the package substrate. Young's modulus (sometimes referred to as the Young modulus) is a mechanical property that measures a material's stiffness.

In addition, in embodiments a thicker die attach layer than normal is used to absorb some of the stress, increasing the height of the die attach layer from the normal range around 25 μm to between 50-150 μm thick. In addition, a thicker die substrate can absorb more stress, and the combination of a thicker die substrate and thicker die attach layer provide added benefits.

In further embodiments a pattern of open cavities is etched in the bottom of the die substrate. The die substrate may be made thicker to provide room for the cavities, as well as being thicker to absorb stress. The cavities form a pattern that further reduces stress by providing open space to absorb some of the transmitted stress due to differences in thermal expansion and contraction. A variety of patterns could be used, such as a perimeter cavity, a simple cross pattern, a cross-hatched pattern, or a circular pattern.

Embodiments provide a micro-electro-mechanical system (MEMS) apparatus for beam steering in a Light Detection and Ranging (LiDAR) system of an autonomous vehicle. A mirror mass has a reflective surface and at least first and second respective sides. First and second supporting torsion springs, wherein the first and second supporting torsion springs have first ends, respectively, connect to the first and second respective sides of the mirror mass, on opposite sides, to support the mirror mass. First and second common terminals connect to the first and second supporting torsion springs, respectively, on second ends of the first and second supporting torsion springs. A plurality of first fingers extend from the mirror mass on first and second sides orthogonal to the first and second supporting torsion springs. First and second bias terminals are opposite the first and second sides of the mirror mass. A plurality of second fingers extend from the first and second bias terminals. The plurality of second fingers are interleaved with the plurality of first fingers and partially overlap the plurality of first fingers. An oxide layer is below the first and second common terminals and the first and second bias terminals. A die substrate is below the oxide layer. A chip package has a chip package substrate. A die attach layer is between the die substrate and the chip package substrate, and is adhesively bonded to both the die substrate and the chip package substrate. The die attach layer has a Young's modulus less than 25,000 or less than 15,000 psi. The die substrate is patterned with a plurality of cavities open to the die attach layer.

Other embodiments provide a method for forming a micro-electromechanical system (MEMS) mirror device. This includes the steps of providing a die substrate, etching a plurality of cavities in the bottom of the die substrate to form a pattern of open cavities, and forming an oxide layer over the die substrate. A MEMS mirror structure is then formed over the oxide layer. The MEMS mirror structure includes:
a mirror mass having a reflective surface and at least first and second respective sides;
first and second supporting torsion springs, wherein the first and second supporting torsion springs have first ends, respectively, connected to the first and second respective sides of the mirror mass, on opposite sides, to support the mirror mass;
first and second common terminals connected to the first and second supporting torsion springs, respectively, on second ends of the first and second supporting torsion springs;
a plurality of first fingers extending from the mirror mass on first and second sides orthogonal to the first and second supporting torsion springs;
first and second bias terminals opposite the first and second sides of the mirror mass; and
a plurality of second fingers extending from the first and second bias terminals, the plurality of second fingers being interleaved with the plurality of first fingers and partially overlapping the plurality of first fingers.
   A chip package is provided having a chip package substrate. Next is attaching a die attach layer between the die substrate and the chip package substrate, and then adhesively bonding the die attach layer to both the die substrate and the chip package substrate. This may be done before or after dicing a wafer into individual dies. A die attach layer with a Young's modulus less than 25,000 or less than 15,000 psi is chosen.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, it should be understood that, although the present system and methods have been specifically disclosed by examples and optional features, modification and variation of the concepts herein disclosed should be recognized by those skilled in the art, and that such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following specification, claims, and accompanying drawings.

### BRIEF DESCRIPTION OF THE DRAWINGS

The features of the various embodiments described above, as well as other features and advantages of certain embodiments of the present invention will, be more apparent from the following detailed description taken in conjunction with the accompanying drawings, in which:

FIG. 1 shows an autonomous vehicle with a LiDAR system, according to certain embodiments;

FIG. 2A shows an example of a light projection operation, according to certain embodiments;

FIG. 2B shows an example of a light detection operation, according to certain embodiments;

FIG. 3A is a diagram of the structure of a prior art MEMS mirror;

FIG. 3B is a sectional view of FIG. 3A along lines A-A;

FIGS. 4A-B illustrate a semiconductor substrate with a MEMS mirror structure and a die attach layer according to embodiments;

FIGS. 5A-D illustrate patterns for a die attach layer according to embodiments;

FIGS. 6A-C are charts illustrating frequency change due to temperature change for different die attach layer patterns according to embodiments;

FIG. 7 is a flow chart illustrating a die attach method according to embodiments;

FIG. 8 is a diagram of a reflective, piezo MEMS mirror with dual axis rotation.

FIG. 9 is a block diagram of a reflective MEMS mirror angle control circuit;

FIG. 10 illustrates a simplified block diagram showing aspects of a LiDAR-based detection system, according to certain embodiments of the invention; and

FIG. 11 illustrates an example computer system that may be utilized to implement techniques disclosed herein, according to certain embodiments of the invention.

### DETAILED DESCRIPTION OF THE INVENTION

Aspects of the present disclosure relate generally to a LiDAR system, and more particularly to scanning an environment with a laser and MEMS-based mirrors, and in particular to minimizing the effect of temperature changes on the MEMS mirror resonant frequency and flatness.

In the following description, various examples of MEMS-based micro mirror structures are described. For purposes of explanation, specific configurations and details are set forth in order to provide a thorough understanding of the embodiments. However, it will be apparent to one skilled in the art that certain embodiments may be practiced or implemented without every detail disclosed. Furthermore, well-known features may be omitted or simplified in order to prevent any obfuscation of the novel features described herein.

The following high level summary is intended to provide a basic understanding of some of the novel innovations depicted in the figures and presented in the corresponding descriptions provided below. Techniques disclosed herein relate generally to microelectromechanical (MEMS) mirrors that can be used in, for example, light detection and ranging (LiDAR) systems or other light beam steering systems. More specifically, and without limitation, disclosed herein are embodiments that provide a micro-electromechanical system (MEMS) die attachment method and mechanism that minimizes the effect of temperature changes on the resonant frequency.

In particular, a die attach layer is between the die substrate and the chip package substrate, and is adhesively bonded to both the die substrate and the chip package substrate. The die attach layer has a Young's modulus less than 25,000 or less than 15,000 psi, meaning that it is relatively soft, not stiff, and thus absorbs more stress. The stress is thus reduced by putting a layer with a low Young's modulus between the semiconductor die and the chip package, such as a silicone adhesive. Young's modulus defines the relationship between stress (force per unit area) and strain (proportional deformation). Young's modulus may be different in different directions in the material. Most metals and ceramics, along with a number of other materials, are isotropic, which means that their mechanical properties are the same in all orientations. Anisotropic materials have a Young's modulus value that depends on the direction of the force vector. For example, composites can be anisotropic. Metals and ceramics can be treated with certain impurities to make their grain structures directional.

A low Young's modulus thus allows stress to be absorbed by the silicone adhesive, rather than being mostly transmitted to the semiconductor die. For MEMS mirror dies, the orientation of the mirror is critical. Thus care must be used when applying pressure to attach the die to the silicon adhesive. The attachment should avoid the silicone adhesive being compressed (squished) such that the die, and thus the mirror, is slightly tilted. Because the angle of the mirror is important down to fractions of a degree of the wavelength of laser light, this causes alignment problems. One solution is to apply pressure on the four corners of the chip, avoiding contact and damage to the sensitive mirror structure. In addition, a partial vacuum may be used to assist the placement. Another solution is using a die attach film, which is less likely to cause tilting because it maintains the same thickness.

Other embodiments reduce stress by etching cavities in the bottom of the die substrate to form a pattern of open cavities. The die substrate is patterned with a plurality of cavities open to the die attach layer. The die substrate may be made thicker to provide room for the cavities. The cavities form a pattern that further reduces stress by providing space to absorb some of the transmitted stress due to differences in thermal expansion and contraction. A variety of patterns could be used, such as a perimeter cavity, a simple cross pattern, a cross-hatched pattern, or a circular pattern.

The detailed discussion below, and accompanying figures, will first describe a general Lidar system incorporating embodiments. Next, the mirror structure that operates at a resonant frequency is described. That is followed by detailed descriptions of the novel die attach layer and manufacturing process of embodiments. A dual axis mirror structure is also described. Next are descriptions of the control systems that can react to the change in resonant frequency with temperature, and the computer systems for controlling the systems.

Generally, aspects of the invention are directed to implementations of light steering, which can be used in a number of different applications. For example, a Light Detection and Ranging (LiDAR) module of an autonomous vehicle may incorporate a light steering system. The light steering system can include a transmitter and receiver system to steer emitted incident light in different directions around a vehicle, and to receive reflected light off of objects around the vehicle using a sequential scanning process, which can be used to determine distances between the objects and the vehicle to facilitate autonomous navigation.

Light steering can be implemented by way of micro-mirror assemblies as part of an array, with each micro-mirror assembly having a movable micro-mirror and an actuator (or multiple actuators). The micro-mirrors and actuators can be formed as microelectromechanical systems (MEMS) on a semiconductor substrate, which allows for the integration of the MEMS with other circuitries (e.g., controller, interface circuits, etc.) on the semiconductor substrate, which can allow for simpler, easier, more robust, and cost-effective manufacturing processes.

In a micro-mirror assembly, a micro-mirror can be mechanically connected (e.g., “anchored”) to the semiconductor substrate via a connection structure (e.g., torsion bar, torsion spring, torsion beam, etc.) to form a pivot point and an axis of rotation. As described herein, “mechanically connected,” or “connected,” can include a direct connection or an indirect connection. For example, the micro-mirror can be indirectly connected to the substrate via a connection structure (e.g., torsion bar or torsion spring) to form a pivot/connection point. The micro-mirror can be rotated around the pivot/connection point (“referred to herein as a pivot point”) on the axis of rotation by an actuator. An electrostatic actuator is typically used; however, any suitable type of actuator may be implemented (e.g., piezoelectric, thermal mechanical, etc.), and one of ordinary skill in the art with the benefit of this disclosure would appreciate the many modifications, combinations, variations, and alternative embodiments thereof.

In some embodiments, each micro-mirror can be configured to be rotated by a rotation angle or moved vertically to reflect (and steer) light towards a target direction. For rotation, the connection structure can be deformed to accommodate the rotation, but the connection structure also has a degree of spring stiffness, which varies with the rotation angle and counters the rotation of the micro-mirror to set a target rotation angle. To rotate a micro-mirror by a target rotation angle, an actuator can apply a torque to the micro-mirror based on the rotational moment of inertia of the mirror, as well as the degree of spring stiffness for a given target rotation angle. Different torques can be applied to rotate (e.g., oscillate) the micro-mirror at or near a resonant frequency to achieve different target rotation angles. The actuator can then remove the torque, and the connection structure can return the micro-mirror back to its default orientation for the next rotation. A vertical actuator, such as an electrostatic force actuator, or a thermal actuator with a piston, can be used in embodiments. The rotation or vertical displacement of the micro-mirror can be repeated in the form of an oscillation, typically at or near a resonant frequency of the micro-mirror based on the mass of the micro-mirror and the spring constant of the connection structure.

In certain embodiments, each micro-mirror can be rotated around two orthogonal axes to provide a first range of angles of projection along a vertical dimension and to provide a second range of angles of projection along a horizontal dimension. The first range and the second range of angles of projection can define a two-dimensional field of view (FOV) in which light is projected to detect/scan an object. The FOV can also define a two-dimensional range of directions of incident lights that can be reflected by the object and detected by the receiver. Less commonly, LiDAR systems may also operate over a single axis (e.g., along a horizontal direction). One of ordinary skill in the art with the benefit of this disclosure would appreciate the many implementations and alternative embodiments thereof.

### Typical System Environment for Certain Embodiments of the Invention

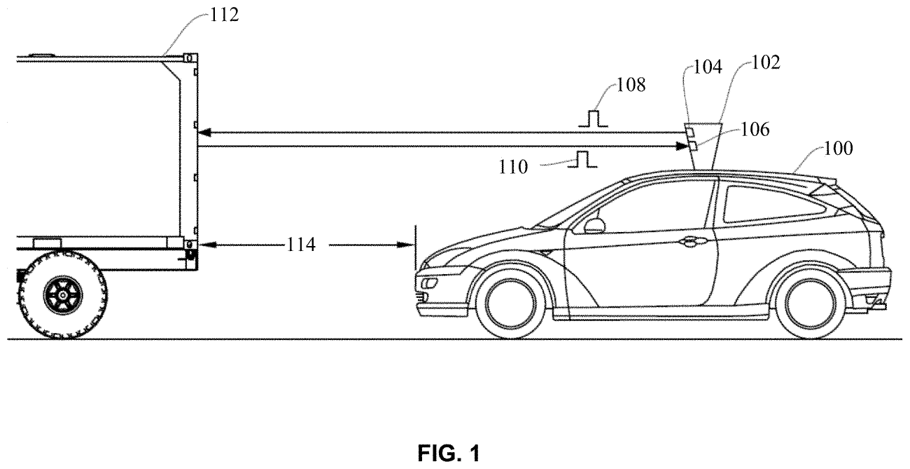

FIG. 1 illustrates an autonomous vehicle 100 in which the various embodiments described herein can be implemented. Autonomous vehicle 100 can include a LiDAR module 102. LiDAR module 102 allows autonomous vehicle 100 to perform object detection and ranging in a surrounding environment. Based on the result of object detection and ranging, autonomous vehicle 100 can drive according to the rules of the road and maneuver to avoid a collision with detected objects. LiDAR module 102 can include a light steering transmitter 104 and a receiver 106. Light steering transmitter 104 can project one or more light signals 108 at various directions (e.g., incident angles) at different times in any suitable scanning pattern, while receiver 106 can monitor for a light signal 110 which is generated by the reflection of light signal 108 by an object. Light signals 108 and 110 may include, for example, a light pulse, a frequency modulated continuous wave (FMCW) signal, an amplitude modulated continuous wave (AMCW) signal, etc. LiDAR module 102 can detect the object based on the reception of light signal 110, and can perform a ranging determination (e.g., a distance of the object) based on a time difference between light signals 108 and 110, as would be appreciated by one of ordinary skill in the art with the benefit of this disclosure. For example, as shown in FIG. 1, LiDAR module 102 can transmit light signal 108 at a direction directly in front of autonomous vehicle 100 at time T1 and receive light signal 110 reflected by an object 112 (e.g., another vehicle) at time T2. Based on the reception of light signal 110, LiDAR module 102 can determine that object 112 is directly in front of autonomous vehicle 100. Moreover, based on the time difference between T1 and T2, LiDAR module 102 can also determine a distance 114 between autonomous vehicle 100 and object 112. Autonomous vehicle 100 can thereby adjust its speed (e.g., slowing or stopping) to avoid collision with object 112 based on the detection and ranging of object 112 by LiDAR module 102.

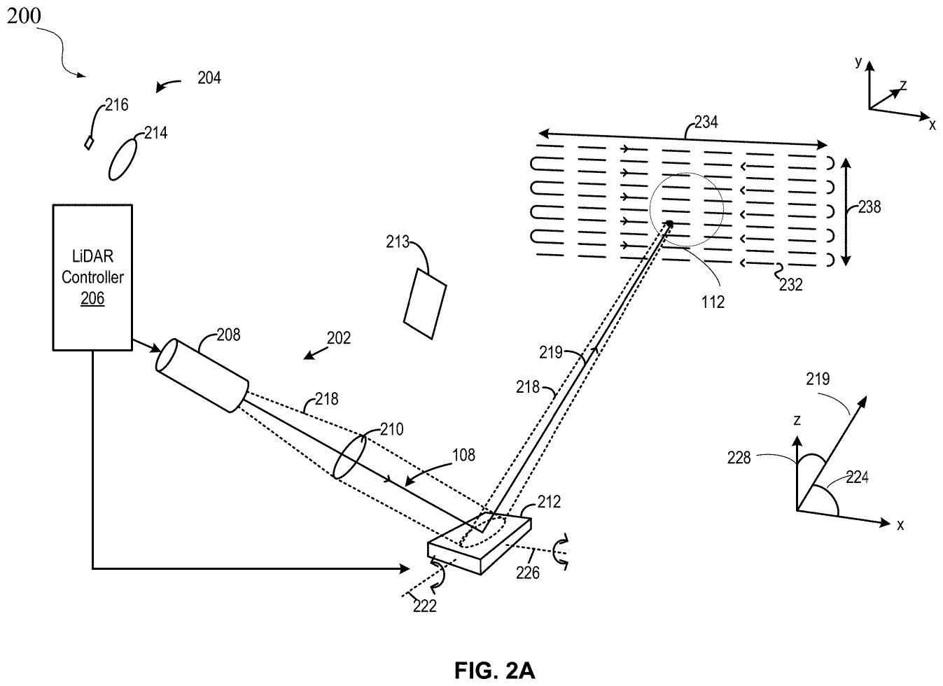

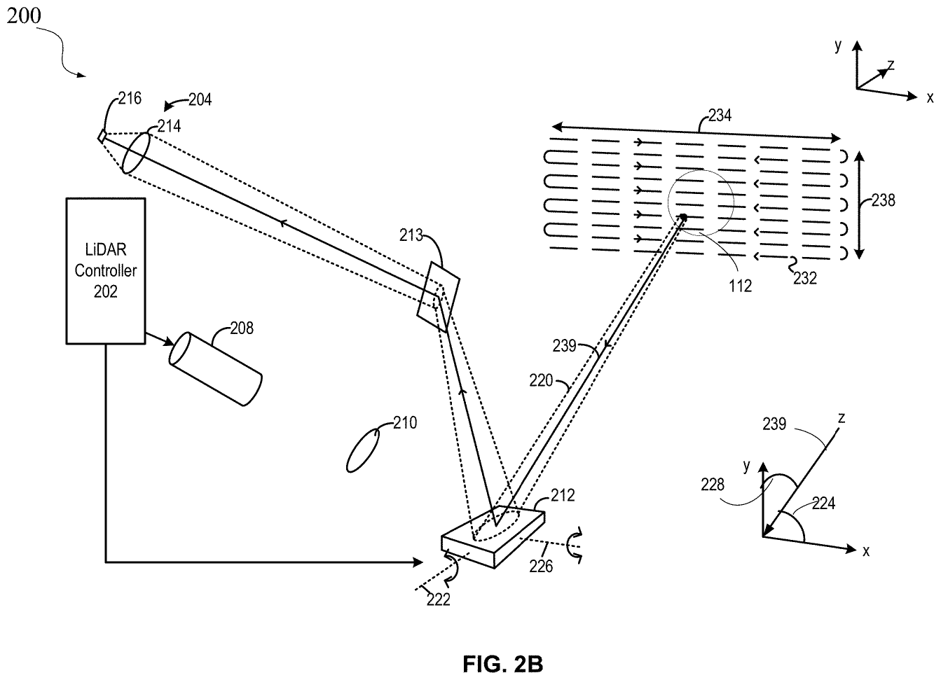

FIG. 2A and FIG. 2B illustrate simplified block diagrams of an example of a LiDAR module 200 according to certain embodiments. LiDAR module 200 may be an example of LiDAR system 102, and may include a transmitter 202, a receiver 204, and LiDAR controller 206, which may be configured to control the operations of transmitter 202 and receiver 204. Transmitter 202 may include a light source 208 and a collimator lens 210, and receiver 204 can include a lens 214 and a photodetector 216. LiDAR module 200 may further include a mirror assembly 212 (also referred to as a “mirror structure”) and a beam splitter 213. In some embodiments, LiDAR module 102, transmitter 202 and receiver 204 can be configured as a coaxial system to share mirror assembly 212 to perform light steering operations, with beam splitter 213 configured to reflect incident light reflected by mirror assembly 212 to receiver 204.

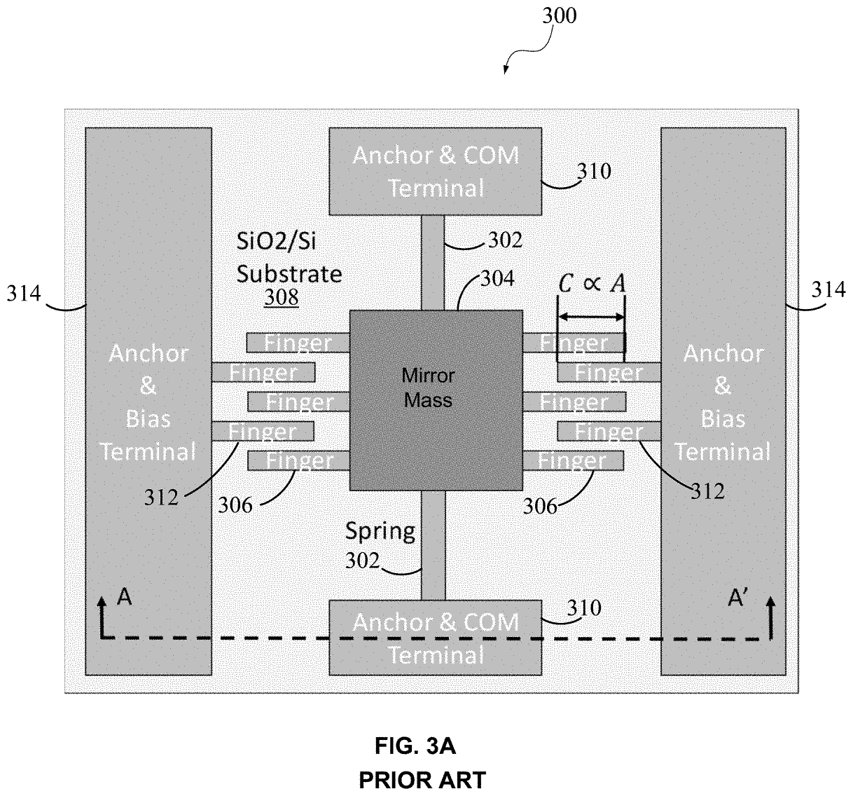

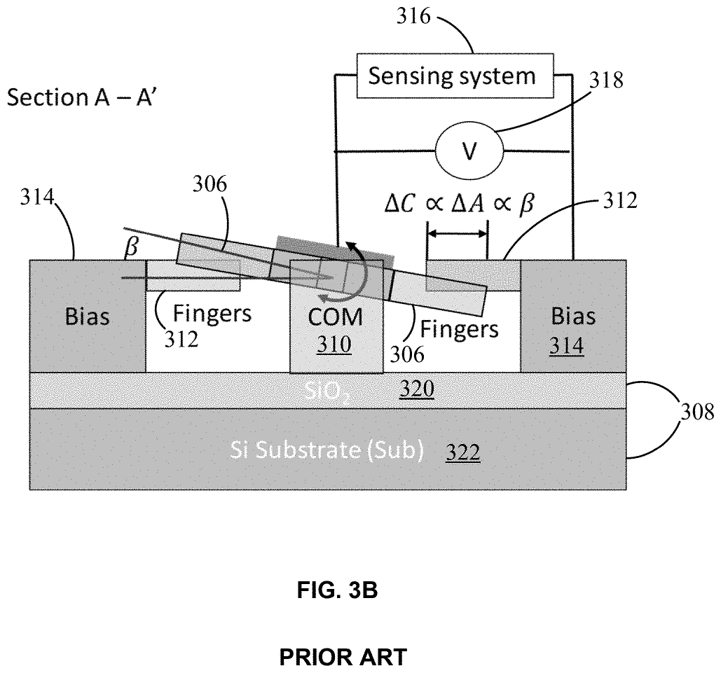

FIG. 2A shows an example of a light projection operation, according to certain embodiments. To project light, LiDAR controller 206 can control light source 208 (e.g., a pulsed laser diode, a source of FMCW signal, AMCW signal, etc.) to transmit light signal 108 as part of light beam 218. Light beam 218 can disperse upon leaving light source 208 and can be converted into collimated light beam 218 by collimator lens 210. Collimated light beam 218 can be incident upon a mirror assembly 212, which can reflect collimated light beam 218 to steer it along an output projection path 219 towards object 112. Mirror assembly 212 can include one or more rotatable mirrors. FIG. 2A illustrates mirror assembly 212 as having one mirror; however, a micro-mirror array may include multiple micro-mirror assemblies that can collectively provide the steering capability described herein. Mirror assembly 212 can further include one or more actuators (not shown in FIG. 2A) to rotate the rotatable mirrors. The actuators can rotate the rotatable mirrors around a first axis 222, and can rotate the rotatable mirrors along a second axis 226. The rotation around first axis 222 can change a first angle 224 of output projection path 219 with respect to a first dimension (e.g., the x-axis), whereas the rotation around second axis 226 can change a second angle 228 of output projection path 219 with respect to a second dimension (e.g., the z-axis). LiDAR controller 206 can control the actuators to produce different combinations of angles of rotation around first axis 222 and second axis 226 such that the movement of output projection path 219 can follow a scanning pattern 232. A range 234 of movement of output projection path 219 along the x-axis, as well as a range 238 of movement of output projection path 219 along the z-axis, can define a FOV. An object within the FOV, such as object 112, can receive and reflect collimated light beam 218 to form reflected light signal, which can be received by receiver 204 and detected by the LiDAR module, as further described below with respect to FIG. 2B. In certain embodiments, mirror assembly 212 can include one or more comb spines with comb electrodes (see, e.g., FIG. 3), as will be described in further detail below.

FIG. 2B shows an example of a light detection operation, according to certain embodiments. LiDAR controller 206 can select an incident light direction 239 for detection of incident light by receiver 204. The selection can be based on setting the angles of rotation of the rotatable mirrors of mirror assembly 212, such that only light beam 220 propagating along light direction 239 gets reflected to beam splitter 213, which can then divert light beam 220 to photodetector 216 via collimator lens 214. With such arrangements, receiver 204 can selectively receive signals that are relevant for the ranging/imaging of object 112 (or any other object within the FOV), such as light signal 110 generated by the reflection of collimated light beam 218 by object 112, and not to receive other signals. As a result, the effect of environmental disturbance on the ranging and imaging of the object can be reduced, and the system performance may be improved.

### Mirror Structure

FIG. 3A is a diagram of the structure of a MEMS mirror. FIG. 3A shows a typical electrostatic MEMS mirror structure 300 with springs (torsion beams) 302, a mirror mass 304, and comb fingers 306, 312. The mirror mass 304 is suspended by mechanical springs or torsion beams 302 which are typically anchored in a SiO₂/silicon substrate 308 and anchored at anchor and COM (sometimes referred to as simply “common” or “COM”) terminals 310. Comb fingers 306 are connected to mirror mass 304, and are interleaved with comb fingers 312 connected to anchor and bias (sometimes referred to as simply “bias”) terminals 314. Terminals 310 provide for common (COM) with the mirror, both providing a driving voltage and sensing a change in capacitance between the fingers 306 connected to mirror mass 304, and interleaved fingers 312 connected to anchor and bias terminals 314. Anchor and bias terminals 314 are connected to a voltage bias, which is typically a combination of a DC and an AC voltage.

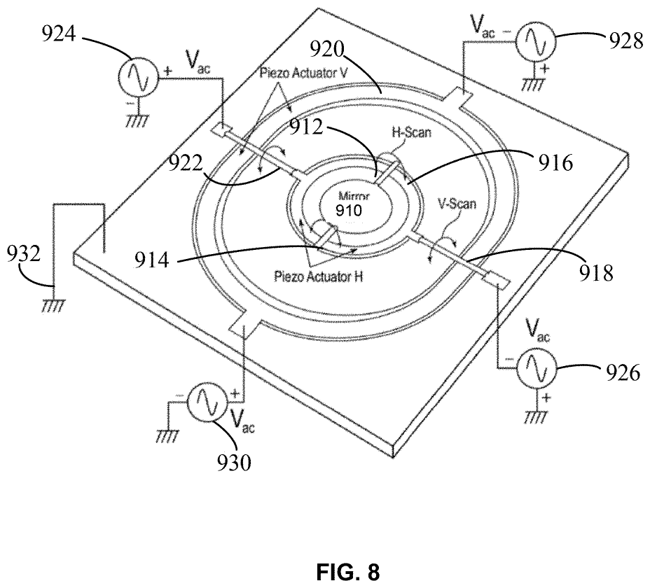

As shown, this structure allows rotation around the axis of the springs/torsion beams 302. In another embodiment not shown in order to not complicate the diagram, additional springs can be provided to give a second, orthogonal axis of rotation of the mirror mass 304 (See FIG. 8 and the accompanying discussion below). Additional interleaved comb fingers are then provided, connected to separate bias and COM anchor terminals.

FIG. 3B is a sectional view of FIG. 3A along lines A-A. As can be seen from FIG. 3B, mirror mass 304 tilts when a driving voltage 318 (V) is applied across the comb fingers 306, 312, between COM terminal 310 and bias terminal 314. Since the overlap area in the fingers changes along with the mirror mass displacement, the capacitance of the comb fingers changes proportionally and it is sensed by sensing system 316 and used as feedback to control the motion of the mirror mass. As shown, the overlap between the fingers 306 and 312 changes, with a change in capacitance (ΔC) that is proportional to the change in overlap area (ΔA), which is proportional to the tilt angle β.

### Die Attachment to Package

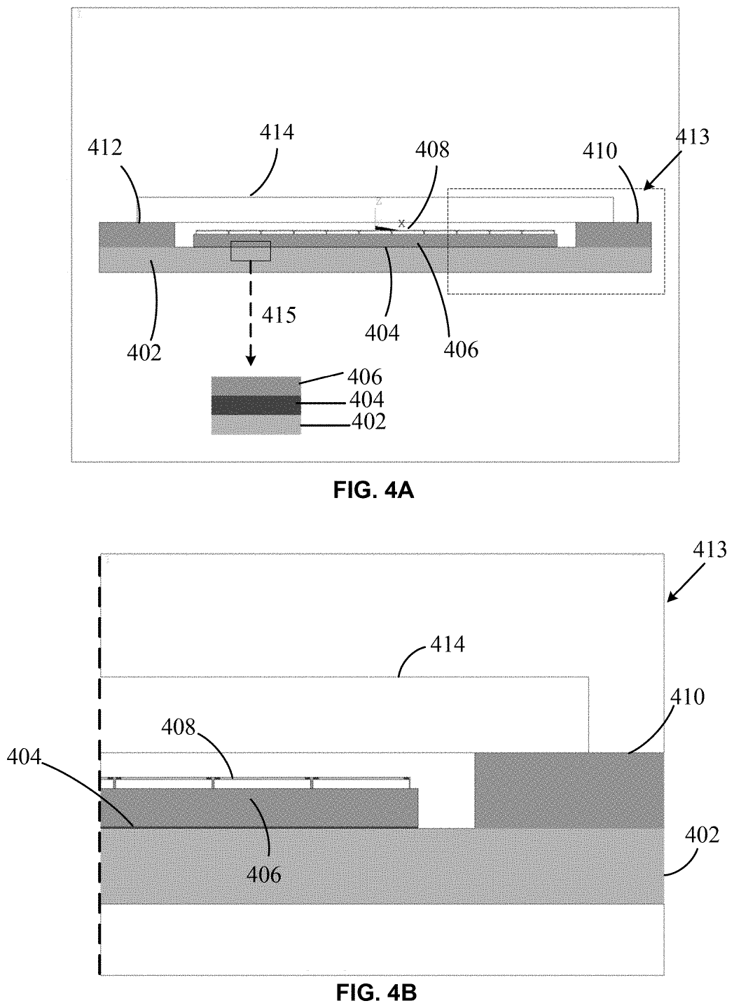

FIGS. 4A-B illustrate a semiconductor substrate with a MEMS mirror structure and a die attach layer according to embodiments. FIG. 4A shows a cross-section of a chip package with a package substrate 402, chip package walls 410 and 412, and a chip package cover 414, which may be a transparent glass or lens in one embodiment. A die attach layer 404 attaches a substrate 406 to the chip package substrate 402. On top of substrate 406 are a number of MEMS mirror structures 408, forming a MEMS mirror array. Arrow 415 shows an enlargement of a portion better illustrating the die attach layer 404 between the chip/die substrate 406 and the package substrate (bottom) 402.

Substrate 406 corresponds to silicon substrate 322 in FIG. 3B. In one embodiment, package substrate 402 is alumina. Chip package walls 410 and 412 may also be alumina (aluminum oxide, Al₂O₃) or another ceramic chip package material such as aluminum nitride (AlN), or another material such as Kovar. Walls 410 and 412 would typically be of the same material as package bottom/substrate 402. In addition, combinations may be used, such as adding alkaline-earth silicates or small amounts of magnesia (MgO) and silica (SiO₂). The die can be attached to the chip package substrate with an epoxy or a die attach film. For a die attach film, the film can be attached to the wafer before dicing. For epoxy based solution, dicing is done first and epoxy is applied between a package and a die. An epoxy may be softer, and squish more easily. This makes a better attachment with less pressure, but the mirror structure may end up tilted and need compensation. A die attach film is usually firmer, and thus there is less risk of tilt of the mirror structure, and less need for compensation. However, more pressure may be needed to achieve contact through the film. Additional pressure can damage the MEMS mirror structure, so it is desirable to have a die attach film that does not require excessive pressure, or the pressure needs to be applied just at the edges of the die. Also, a partial vacuum can help the die attach process. A full vacuum can be used in a laboratory setting, but usually isn't economical for a commercial plant.

As described in the background, stresses can be transferred to the mirror structures due to a mismatch between the coefficient of thermal expansion (CTE) of the package substrate 402 and the chip substrate 406. One method for addressing this is to provide a die attach layer 404 that compensates for the stress. One method for reducing the effect of CTE mismatch due to die attachment is to use a die attach material with a relatively low Young's modulus. The low Young's modulus of a die attach material results in the die attach material itself being deformed more than the chip/device substrate and the package substrate, accommodating and relieving some of the stress due to the different degrees of expansion during a temperature change. In effect, the die attach layer can act as a sort of thermal shock absorber. A thicker die attach layer will improve this stress absorbing characteristic. The die attach layer can be a glue or epoxy in some embodiments, or a film with adhesive in other embodiments. As noted above, however, with standard die attach glues, the chip can tilt during attachment as a result of the die being squished different amounts at different parts of the die. This can result in a misalignment of the mirror structures. Accordingly, some embodiments of the present invention replace such a chip attach glue with a die attach film, which is more rigid and will not squish to the extent of a die attached glue. In order to provide the stress relieving characteristics desired, the die attach film is made thicker than normal.

Additionally, the inventors determined that the stress relief properties of a die attach layer could be further improved by cutting a pattern into the bottom of the chip die. This is another method for reducing the effect of CTE mismatch—providing a pattern of gaps to absorb stress in the bottom surface of a device. Patterns cut into the bottom surface of the device die reduce the lateral stiffness on the bottom, making the bottom easier to deform and take away some of the stress due to the mismatch in thermal expansion of the device and its enclosure. A variety of different patterns of cuts or cavities can be used. A pattern that simply makes the interior hollow is an alternative, but may not be as effective as other patterns. In one embodiment, the depth of the cut is 25-300 microns or 50-150 microns. Alternately, a deeper cut can be used but would require more time or deep etch equipment. The etch depth is limited by the thickness of the Si substrate layer thickness and it typically is 300-800 μm. In one embodiment with a patterned (with cavities) substrate bottom, a die attach material 25-50 μm thick is used for die tilt stability. Etched-in areas would have a thicker die attach material if an epoxy die attach material is used, since the epoxy would at least partially fill the etched cavities.

Relieving the stress limits the effects of temperature change on the resonant frequency and flatness of the MEMS mirrors. The resonant frequency is dependent on the tension of the torsion beam that the mirror rotates around. Ideally, the tension would be relatively constant with temperature. However, the silicon CTE is low compared to typical package materials, such as ceramics. Thus, the materials expand or contract different amounts with temperature change, affecting the torsion beam tension and thus the resonant frequency. A thicker die attach material helps. The die attach layer can deform when there is a mismatch between the CTE of the silicon substrate of the die, and the CTE of the package material. The attached material expands more than silicon if the temperature goes up, and due to material's softness silicon does not expand as much, resulting in less pressure on the torsion beams. In addition, making the silicon substrate itself thicker can help by providing more space for stress to dissipate, and can also provide room for etching cavities.

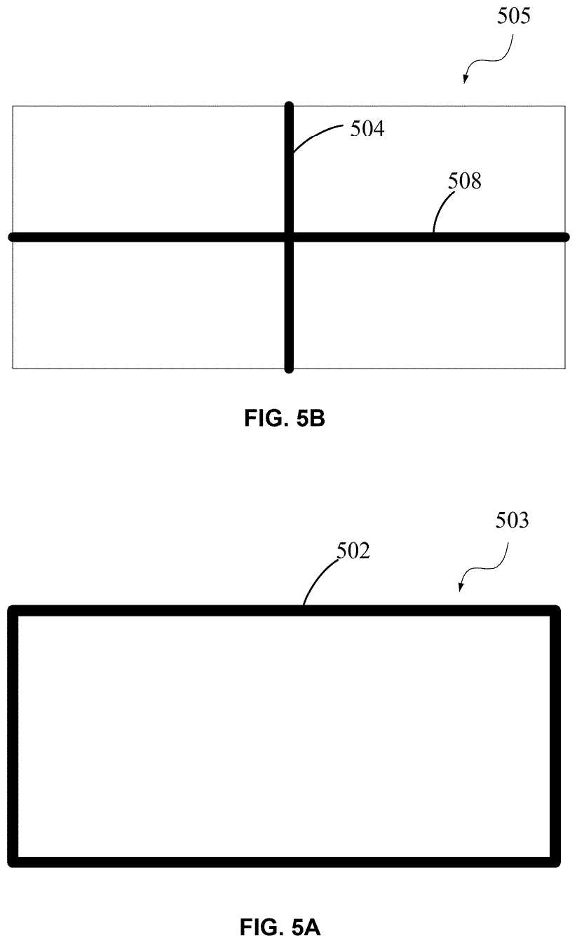

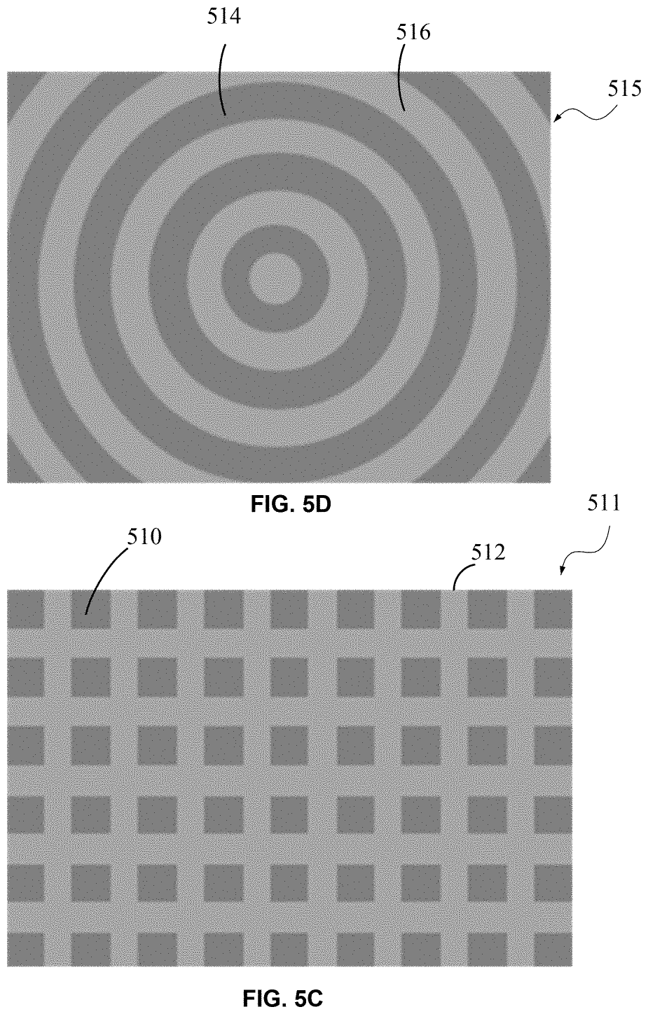

FIG. 4B is a more detailed diagram of a portion of the structure of FIG. 4A, showing test set-up modifications to determine the efficacy of different patterns. In addition to the pattern, and the lower Young's modulus, and the thickness of the die attach layer, a thicker chip/die silicon substrate is used. Instead of a standard 400 μm thickness substrate, another 100 μm are added, giving a total substrate thickness for substrate 406 of 500 μm. To simulate a pattern etched into the bottom of the substrate, a thick die attach layer 404, in one embodiment, is placed on top of a thinner, standard die attach film 414. This provides a gap area 413 which would correspond to an etched perimeter pattern in the bottom of the die substrate, corresponding to perimeter line 502 shown for pattern 503 in FIG. 5A.

A die attach film with a low Young's modulus is chosen to provide the desired stress release. In particular, a film with a Young's modulus that is less than 15,000 psi is used. Alternately, a Young's modulus between 1,000 psi and 15,000 psi is chosen.

Die attach layer 404, in one embodiment, is between 25-150 μm thick (1 mil [thousandth of an inch]-6 mil). Alternately, it could be 15-175 μm thick. More particularly, it is between 50-125 μm thick. In one embodiment, it is 100 μm thick+−10%.

FIGS. 5A-D illustrate patterns for a die attach layer according to embodiments. FIG. 5A shows a simple perimeter pattern as discussed above, with a perimeter edge 502. As shown in FIG. 4B, this was simulated by using two different thicknesses of die attach material, with the thicker die attach film only covering the central part of pattern 503 of FIG. 5A. Similarly, as shown in FIG. 5B, four different thicker die attach films were placed over a single, thinner die attach material, leaving gaps 504 and 508, to simulate a cross edge pattern 505 as shown in FIG. 5B.

The patterns comprise cavities etched in the bottom of the die substrate. In one embodiment, the cavities are 100 μm wide and 100 μm deep. Alternately, the cavities are 50-150 μm wide and 25-300 μm deep. The cavity width could vary by a lot. For instance, the width of cavities in FIG. 5A could span tens of mm.

FIG. 5C illustrates a combination of vertical and horizontal cuts, such as cut 512, effectively making many micro pillars 510. This provides the cross-hatched pattern 511 shown in FIG. 5C. As shown, the width of the cuts 512 is approximately the same as the width of the micro pillars 510. However, in alternate embodiments, the width of the cuts could be made larger with smaller micro pillars, or vice-versa.

FIG. 5D illustrates concentric cuts starting from around the center of a die. A series of concentric cuts such as 516 leave a series of concentric walls 514 to form a pattern 515. The examples of FIGS. 5A-D are only illustrative of some patterns which could be used. Any other pattern which provides cuts that can relieve stress could be used. For example, diagonal cuts could be used, leaving triangular pillars. Alternately, the width and spacing of the cuts can be varied. For example, the cuts might be wider and/or closer near the center of the die substrate, and more spaced and/or narrower near the perimeters to provide a firmer attachment around the perimeter (edges).

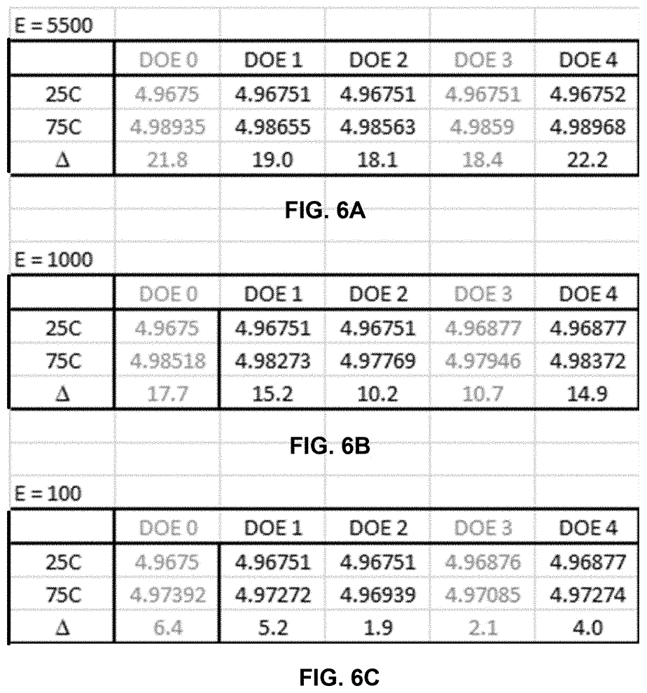

FIGS. 6A-C are charts illustrating frequency change due to temperature change for different die attach layer patterns according to embodiments. The test set up for these pattern measurements used the different thicknesses and sizes of die attach films as described with respect to FIGS. 4A and 5A-B. The charts illustrate four different simulated patterns, labelled DOE (Design of Experiment)1-4. The different DOEs are as follows:

DOE 0 is a standard die and die attach layer/film without anything more added.

DOE 1 simply adds another 100 μm in thickness to the 500 m all Si die substrate layer 406 of FIG. 4B. Thus, the Si die substrate layer basically becomes 600 μm thick.

DOE 2 simply uses a thicker die attach layer, with a 100 μm thick die attach material. This layer, shown as die attach layer 404 in FIG. 4B, is placed on top of the standard, 25.4 μm thick die attach layer 414. Thus, the die attach layer basically becomes 125.4 μm thick

DOE 3 corresponds to pattern 505 shown in FIG. 5B. A 100 μm deep cross was created on the back of the die substrate. The remaining four rectangular 100 μm thick die attach film layers were provided and fill in the four rectangular areas. This helps to stabilize the mirror structures, minimizing tilting by keeping the die attach material 25.4 μm thick under the patterned Si substrate.

DOE 4 provides a 100 μm thick die attach layer, leaving a perimeter gap 502 as shown in FIG. 5A. The gap is 100 μm wide, and the height/depth of the gap/cavity is the same as the die attach layer thickness, also 100 μm. In addition, the Si substrate of the die is extruded from its base along the edges, in the perimeter gap 502. This helps to stabilize the mirror structures from tilting by keeping die attach material layer 25.4 μm thick under the patterned Si substrate. As described before, the die attach layer can be an epoxy or a film. If an epoxy is used with a pattern of cavities on the bottom of the substrate, the epoxy will be squeezed into the cavities, and thus the die attach layer will be thicker underneath the cavities.

The FIG. 6A chart shows simulation test results for a standard die attach material with a Young's modulus (E) of 5500 Mpa (797,500 psi). The first two rows show the resonant frequency in kilohertz (kHz), while the last row shows the change (A) in resonant frequency in hertz (Hz). As can be seen, the change in the resonant frequency between 75 and 25 degrees centigrade (C) ranges from 18-22 Hz.

The FIG. 6B chart shows simulation test results for a softer die attach material with a Young's modulus (E) of 1000 Mpa 9 (145,000 psi). As can be seen, standard DOE 0 still has a high resonant frequency change of 17.7 Hz, but the resonant frequency change for DOE 2 and DOE 3 is much lower, at 10.2 and 10.7 Hz, respectively.

The FIG. 6C chart shows simulation test results for a very soft die attach material with a Young's modulus (E) of 100 Mpa (14,500 psi) As can be seen, standard DOE 0 resonant frequency change is reduced to only 6.4 Hz, while the resonant frequency change for DOE 2 and DOE 3 is much lower, at 1.9 and 2.1 Hz, respectively.

The simulation thus shows that the resonant frequency change due to temperature variation can be reduced by (1) a softer die attach material (lower Young's modulus) or (2) a thicker die attach material (DOE 2), or a cross pattern in the substrate (DOE 3). Also, with certain patterned Si layers (DOE 3), the resonant frequency change due to temperature variation can be reduced to a similar degree as using a thicker die attach layer. The use of a patterned silicon layer provides (1) better optical tilt control during assembly than with a thicker die attach layer, and (2) better optical tilt stability by using a thinner die attach layer between the die bottom surface and the package surface.

In one embodiment, the die attach layer is a film composed of an adhesive layer for fixing a semiconductor chip in a dicing step, and an adhesive layer attached to a back surface of the chip in a die bonding step and attached to a wiring board such as a lead frame. The packaging process using such a die-attach film includes a dicing step of cutting the wafer into chips or dies. A die bonding step attaches the separated chips to a mounting plate of a circuit film or lead frame. A wire bonding step connects a circuit pattern such as a chip pad and a lead frame provided on the semiconductor chip with an electrical connection means such as a wire. In order to protect the internal circuit and other components of the semiconductor chip, a molding process for enclosing the outside with an encapsulate is included.

In one example, the thickness ratio (adhesive/film) may be in the range of 0.15 to 0.5. Examples of plastic films include an olefin-based film such as polypropylene film or polyethylene film; Polyester-based films such as polyethylene terephthalate film; Polycarbonate film; Polyvinyl chloride film; Polytetrafluoroethylene film; Polybutene film; Polybutadiene film; Vinyl chloride copolymer film; Ethylene-vinyl acetate copolymer films; Ethylene-propylene copolymer film; or a mixture of one or more kinds of ethylene-ethyl acrylate copolymer films and the like, but is not limited thereto. The heterogeneous mixing of the base films in the above means a film which the base film is composed of two or more laminated films of the above-described films or is prepared from the copolymer of the above-mentioned resins. Such base films may also be subjected to conventional physical or chemical treatments, such as matt treatment, corona discharge treatment, primer treatment or crosslinking treatment, as necessary.

In addition, when the ultraviolet curable pressure-sensitive adhesive is used in the adhesive portion, the base film is preferably excellent in the ultraviolet transmittance, for example, may have a UV transmittance of 70% or more, preferably 90% or more. Adhesive examples include an ultraviolet curable adhesive or a thermosetting adhesive. When using an ultraviolet curable adhesive, adhesive force is reduced by irradiating an ultraviolet-ray from the base film side. In the case of a thermosetting adhesive, appropriate heat is applied and an adhesive force is reduced.

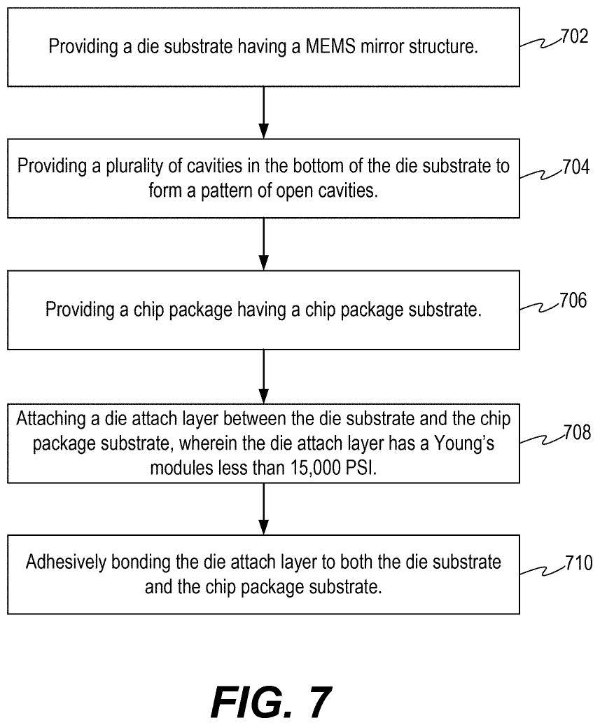

FIG. 7 is a flow chart illustrating a die attach method according to embodiments. Shown is a method for forming a micro-electromechanical system (MEMS) mirror chip. Step 702 is providing a die substrate having a MEMS mirror structure. Step 704 providing a plurality of cavities in the bottom of the die substrate to form a pattern of open cavities. As described above, the MEMS mirror structure includes:
a mirror mass having a reflective surface and at least first and second respective sides;
first and second supporting torsion springs, wherein the first and second supporting torsion springs have first ends, respectively, connected to the first and second respective sides of the mirror mass, on opposite sides, to support the mirror mass;
first and second common terminals connected to the first and second supporting torsion springs, respectively, on second ends of the first and second supporting torsion springs;
a plurality of first fingers extending from the mirror mass on first and second sides orthogonal to the first and second supporting torsion springs;
first and second bias terminals opposite the first and second sides of the mirror mass; and
a plurality of second fingers extending from the first and second bias terminals, the plurality of second fingers being interleaved with the plurality of first fingers and partially overlapping the plurality of first fingers.

Step 706 is providing a chip package having a chip package substrate. Step 708 is attaching a die attach layer between the die substrate and the chip package substrate. Step 710 is adhesively bonding the die attach layer to both the die substrate and the chip package substrate. A die attach layer with a Young's modulus less than 15,000 psi is chosen. The die attach layer may be a film that is attached before the chip is diced into individual die.

In sum, embodiments of the present invention provide a micro-electromechanical system (MEMS) apparatus for beam steering in a Light Detection and Ranging (LiDAR) system 102 of an autonomous vehicle 100. A mirror mass 304 has a reflective surface and at least first and second respective sides. First and second supporting torsion springs 302 are formed, wherein the first and second supporting torsion springs have first ends, respectively, connected to the first and second respective sides of the mirror mass, on opposite sides, to support the mirror mass. First and second common terminals 310 are connected to the first and second supporting torsion springs, respectively, on second ends of the first and second supporting torsion springs. A plurality of first fingers 306 extend from the mirror mass on first and second sides orthogonal to the first and second supporting torsion springs. First and second bias terminals 314 are opposite the first and second sides of the mirror mass. A plurality of second fingers 312 extend from the first and second bias terminals. The plurality of second fingers are interleaved with the plurality of first fingers and partially overlap the plurality of first fingers. An oxide layer is below the first and second common terminals and the first and second bias terminals. A die substrate 322 is below the oxide layer. A chip package has a chip package substrate 402. A die attach layer 404 is between the die substrate and the chip package substrate, and is adhesively bonded to both the die substrate and the chip package substrate. The die attach layer has a Young's modulus less than 15,000 psi. The die substrate is patterned with a plurality of cavities (502, 504, 508, 512, 516) open to the die attach layer.

### Dual Axis Mirror

FIG. 8 is a diagram of a reflective, piezo MEMS mirror with dual axis rotation, according to embodiments. In this embodiment, the piezo MEMS mirror 910 includes a reflective mirror 910 at its center, which is supported by two orthogonally pivoting axes composed of thin regions 912 and 914 in one direction, and 918 and 922 in another, orthogonal direction. Each of the axes are connected to voltages to bias the mirror at the desired angle, with bias voltages 924, 926 in a first direction, and 928, 930 and a second direction. The substrate is grounded to a ground 932. Along one axis, Piezo actuator 916 is used, while along the other access, a Piezo actuator 920 is used. The vertical scan and the horizontal scan are controlled via the respective piezoelectric actuators. By applying oscillating electrical voltages to the respective piezoelectric actuators, the mirror is caused to oscillate, thereby causing appropriate scanning.

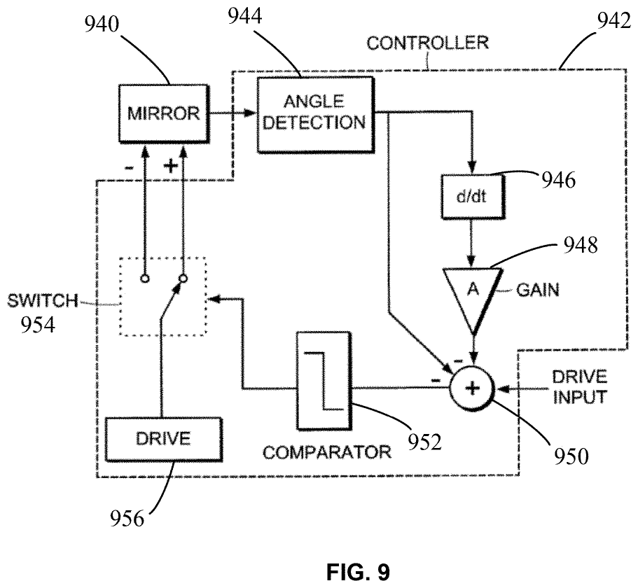

FIG. 9 is a block diagram of a reflective MEMS mirror angle control circuit, according to embodiments. The angle of a mirror 940 is detected by an angle detector 944, such as by detecting a change in capacitance as the mirror rotates in a manner known by those of skill in the art. Angle detector 944 is part of a controller 942 which also includes a differentiator circuit 946 and amplifier 948, the output of which is provided to a summing circuit 950. Summing circuit 950 receives a drive input and provides it to a comparator 952 which compares the desired angle to the measured angle and provides an appropriate input to a switch 954. The switch connects a drive current 956 between different positions to drive the angle of mirror 940 to either a more positive or more negative angle. As understood by those skilled in the art, multiple loops using the same scheme can be used to control multiple axes of rotation.

### Example LiDAR System Implementing Aspects of Embodiments Herein

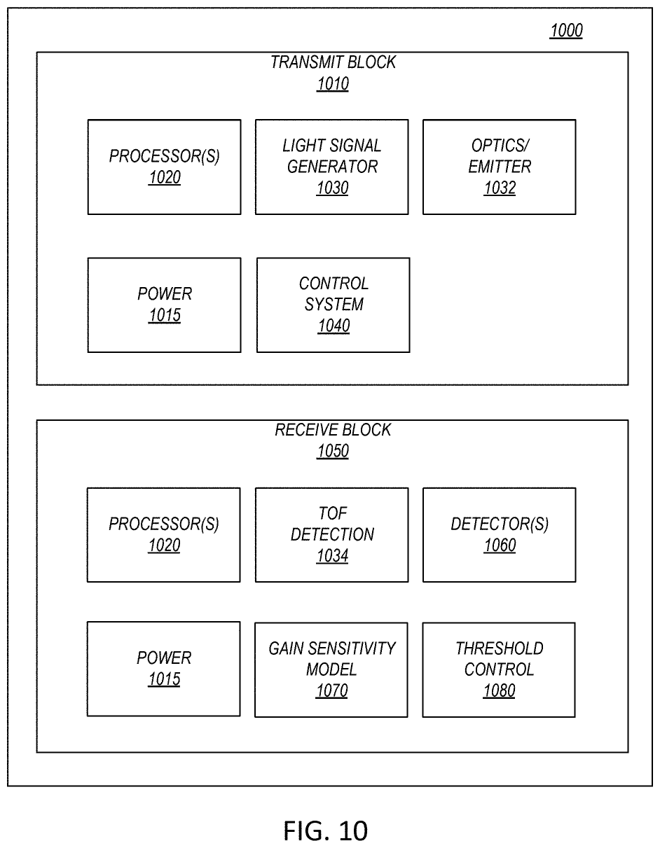

The die attach system and method described herein compensates for changes in resonant frequency with temperature, which allows systems with a narrow range of control to be used. Those control systems, into which the present invention is integrated, will now be described. FIG. 10 illustrates a simplified block diagram showing aspects of a LiDAR-based detection system 1000, according to certain embodiments. System 1000 may be configured to transmit, detect, and process LiDAR signals to perform object detection as described above with regard to LiDAR system 100 described in FIG. 1. In general, a LiDAR system 1000 includes one or more transmitters (e.g., transmit block 1010) and one or more receivers (e.g., receive block 1050). LiDAR system 1000 may further include additional systems that are not shown or described to prevent obfuscation of the novel features described herein.

Transmit block 1010, as described above, can incorporate a number of systems that facilitate that generation and emission of a light signal, including dispersion patterns (e.g., 360 degree planar detection), pulse shaping and frequency control, Time-Of-Flight (TOF) measurements, and any other control systems to enable the LiDAR system to emit pulses in the manner described above. In the simplified representation of FIG. 10, transmit block 1010 can include processor(s) 1020, light signal generator 1030, optics/emitter module 1032, power block 1015 and control system 1040. Some of all of system blocks 1020-1040 can be in electrical communication with processor(s) 1020.

In certain embodiments, processor(s) 1020 may include one or more microprocessors (μCs) and can be configured to control the operation of system 1000. Alternatively or additionally, processor 1020 may include one or more microcontrollers (MCUs), digital signal processors (DSPs), or the like, with supporting hardware, firmware (e.g., memory, programmable I/Os, etc.), and/or software, as would be appreciated by one of ordinary skill in the art. Alternatively, MCUs, μCs, DSPs, ASIC, programmable logic device, and the like, may be configured in other system blocks of system 1000. For example, control system block 1040 may include a local processor to certain control parameters (e.g., operation of the emitter). Processor(s) 1020 may control some or all aspects of transmit block 1010 (e.g., optics/emitter 1032, control system 1040, dual sided mirror 220 position as shown in FIG. 1, position sensitive device 250, etc.), receive block 1050 (e.g., processor(s) 1020) or any aspects of LiDAR system 1000. In some embodiments, multiple processors may enable increased performance characteristics in system 1000 (e.g., speed and bandwidth), however multiple processors are not required, nor necessarily germane to the novelty of the embodiments described herein. Alternatively or additionally, certain aspects of processing can be performed by analog electronic design, as would be understood by one of ordinary skill in the art.

Light signal generator 1030 may include circuitry (e.g., a laser diode) configured to generate a light signal, which can be used as the LiDAR send signal, according to certain embodiments. In some cases, light signal generator 1030 may generate a laser that is used to generate a continuous or pulsed laser beam at any suitable electromagnetic wavelengths spanning the visible light spectrum and non-visible light spectrum (e.g., ultraviolet and infra-red). In some embodiments, lasers are commonly in the range of 600-1200 nm, although other wavelengths are possible, as would be appreciated by one of ordinary skill in the art.

Optics/Emitter block 1032 (also referred to as transmitter 1032) may include one or more arrays of mirrors (including but not limited to dual sided mirror 220 as described above in FIGS. 1-6) for redirecting and/or aiming the emitted laser pulse, mechanical structures to control spinning and/or moving of the emitter system, or other system to affect the system field-of-view, as would be appreciated by one of ordinary skill in the art with the benefit of this disclosure. For instance, some systems may incorporate a beam expander (e.g., convex lens system) in the emitter block that can help reduce beam divergence and increase the beam diameter. These improved performance characteristics may mitigate background return scatter that may add noise to the return signal. In some cases, optics/emitter block 1032 may include a beam splitter to divert and sample a portion of the pulsed signal. For instance, the sampled signal may be used to initiate the TOF clock. In some cases, the sample can be used as a reference to compare with backscatter signals. Some embodiments may employ micro-electro-mechanical systems (MEMS) mirrors that can reorient light to a target field. Alternatively or additionally, multi-phased arrays of lasers may be used. Any suitable system may be used to emit the LiDAR send pulses, as would be appreciated by one of ordinary skill in the art.

Power block 1015 can be configured to generate power for transmit block 1010, receive block 1050, as well as manage power distribution, charging, power efficiency, and the like. In some embodiments, power management block 1015 can include a battery (not shown), and a power grid within system 1000 to provide power to each subsystem (e.g., control system 1040, etc.). The functions provided by power management block 1015 may be subsumed by other elements within transmit block 1010, or may provide power to any system in LiDAR system 1000. Alternatively, some embodiments may not include a dedicated power block and power may be supplied by a number of individual sources that may be independent of one another.

Control system 1040 may control aspects of light signal generation (e.g., pulse shaping), optics/emitter control, TOF timing, or any other function described herein. In some cases, aspects of control system 1040 may be subsumed by processor(s) 1020, light signal generator 1030, or any block within transmit block 1010, or LiDAR system 1000 in general.

Receive block 1050 may include circuitry configured to detect a process a return light pulse to determine a distance of an object, and in some cases determine the dimensions of the object, the velocity and/or acceleration of the object, and the like. Processor(s) 1065 may be configured to perform operations such as processing received return pulses from detectors(s) 1060, controlling the operation of TOF module 1034, controlling threshold control module 1080, or any other aspect of the functions of receive block 1050 or LiDAR system 1000 in general.

TOF module 1034 may include a counter for measuring the time-of-flight of a round trip for a send and return signal. In some cases, TOF module 1034 may be subsumed by other modules in LiDAR system 1000, such as control system 1040, optics/emitter 1032, or other entity. TOF modules 1034 may implement return “windows” that limit a time that LiDAR system 1000 looks for a particular pulse to be returned. For example, a return window may be limited to a maximum amount of time it would take a pulse to return from a maximum range location (e.g., 250 m). Some embodiments may incorporate a buffer time (e.g., maximum time plus 10%). TOF module 1034 may operate independently or may be controlled by other system block, such as processor(s) 1020, as described above. In some embodiments, transmit block may also include a TOF detection module. One of ordinary skill in the art with the benefit of this disclosure would appreciate the many modification, variations, and alternative ways of implementing the TOF detection block in system 1000.

Detector(s) 1060 may detect incoming return signals that have reflected off of one or more objects. In some cases, LiDAR system 1000 may employ spectral filtering based on wavelength, polarization, and/or range to help reduce interference, filter unwanted frequencies, or other deleterious signals that may be detected. Typically, detector(s) 1060 can detect an intensity of light and records data about the return signal (e.g., via coherent detection, photon counting, analog signal detection, or the like). Detector (s) 1060 can use any suitable photodetector technology including solid state photodetectors (e.g., silicon avalanche photodiodes, complimentary metal-oxide semiconductors (CMOS), charge-coupled devices (CCD), hybrid CMOS/CCD devices) or photomultipliers. In some cases, a single receiver may be used or multiple receivers may be configured to operate in parallel.

Gain sensitivity model 1070 may include systems and/or algorithms for determining a gain sensitivity profile that can be adapted to a particular object detection threshold. The gain sensitivity profile can be modified based on a distance (range value) of a detected object (e.g., based on TOF measurements). In some cases, the gain profile may cause an object detection threshold to change at a rate that is inversely proportional with respect to a magnitude of the object range value. A gain sensitivity profile may be generated by hardware/software/firmware, or gain sensor model 1070 may employ one or more look up tables (e.g., stored in a local or remote database) that can associate a gain value with a particular detected distance or associate an appropriate mathematical relationship there between (e.g., apply a particular gain at a detected object distance that is 10% of a maximum range of the LiDAR system, apply a different gain at 15% of the maximum range, etc.). In some cases, a Lambertian model may be used to apply a gain sensitivity profile to an object detection threshold. The Lambertian model typically represents perfectly diffuse (matte) surfaces by a constant bidirectional reflectance distribution function (BRDF), which provides reliable results in LiDAR system as described herein. However, any suitable gain sensitivity profile can be used including, but not limited to, Oren-Nayar model, Nanrahan-Krueger, Cook-Torrence, Diffuse BRDF, Limmel-Seeliger, Blinn-Phong, Ward model, HTSG model, Fitted Lafortune Model, or the like. One of ordinary skill in the art with the benefit of this disclosure would understand the many alternatives, modifications, and applications thereof.

Threshold control block 1080 may set an object detection threshold for LiDAR system 1000. For example, threshold control block 1080 may set an object detection threshold over a certain a full range of detection for LiDAR system 1000. The object detection threshold may be determined based on a number of factors including, but not limited to, noise data (e.g., detected by one or more microphones) corresponding to an ambient noise level, and false positive data (typically a constant value) corresponding to a rate of false positive object detection occurrences for the LiDAR system. In some embodiments, the object detection threshold may be applied to the maximum range (furthest detectable distance) with the object detection threshold for distances ranging from the minimum detection range up to the maximum range being modified by a gain sensitivity model (e.g., Lambertian model).

Although certain systems may not expressly discussed, they should be considered as part of system 1000, as would be understood by one of ordinary skill in the art. For example, system 1000 may include a bus system (e.g., CAMBUS) to transfer power and/or data to and from the different systems therein. In some embodiments, system 1000 may include a storage subsystem (not shown). A storage subsystem can store one or more software programs to be executed by processors (e.g., in processor(s) 1020). It should be understood that “software” can refer to sequences of instructions that, when executed by processing unit(s) (e.g., processors, processing devices, etc.), cause system 1000 to perform certain operations of software programs. The instructions can be stored as firmware residing in read only memory (ROM) and/or applications stored in media storage that can be read into memory for processing by processing devices. Software can be implemented as a single program or a collection of separate programs and can be stored in non-volatile storage and copied in whole or in-part to volatile working memory during program execution. From a storage subsystem, processing devices can retrieve program instructions to execute in order to execute various operations (e.g., software-controlled spring auto-adjustment, etc.) as described herein. Some software controlled aspects of LiDAR system 1000 may include aspects of gain sensitivity model 1070, threshold control 1080, control system 1040, TOF module 1034, or any other aspect of LiDAR system 1000.

It should be appreciated that system 1000 is meant to be illustrative and that many variations and modifications are possible, as would be appreciated by one of ordinary skill in the art. System 1000 can include other functions or capabilities that are not specifically described here. For example, LiDAR system 1000 may include a communications block (not shown) configured to enable communication between LiDAR system 1000 and other systems of the vehicle or remote resource (e.g., remote servers), etc., according to certain embodiments. In such cases, the communications block can be configured to provide wireless connectivity in any suitable communication protocol (e.g., radio-frequency (RF), Bluetooth, BLE, infra-red (IR), ZigBee, Z-Wave, Wi-Fi, or a combination thereof).

While system 1000 is described with reference to particular blocks (e.g., threshold control block 1080), it is to be understood that these blocks are defined for understanding certain embodiments of the invention and is not intended to imply that embodiments are limited to a particular physical arrangement of component parts. The individual blocks need not correspond to physically distinct components. Blocks can be configured to perform various operations, e.g., by programming a processor or providing appropriate processes, and various blocks may or may not be reconfigurable depending on how the initial configuration is obtained. Certain embodiments can be realized in a variety of apparatuses including electronic devices implemented using any combination of circuitry and software. Furthermore, aspects and/or portions of system 1000 may be combined with or operated by other sub-systems as informed by design. For example, power management block 1015 and/or threshold control block 1080 may be integrated with processor(s) 1020 instead of functioning as separate entities.

### Example Computer Systems Implementing Aspects of Embodiments Herein

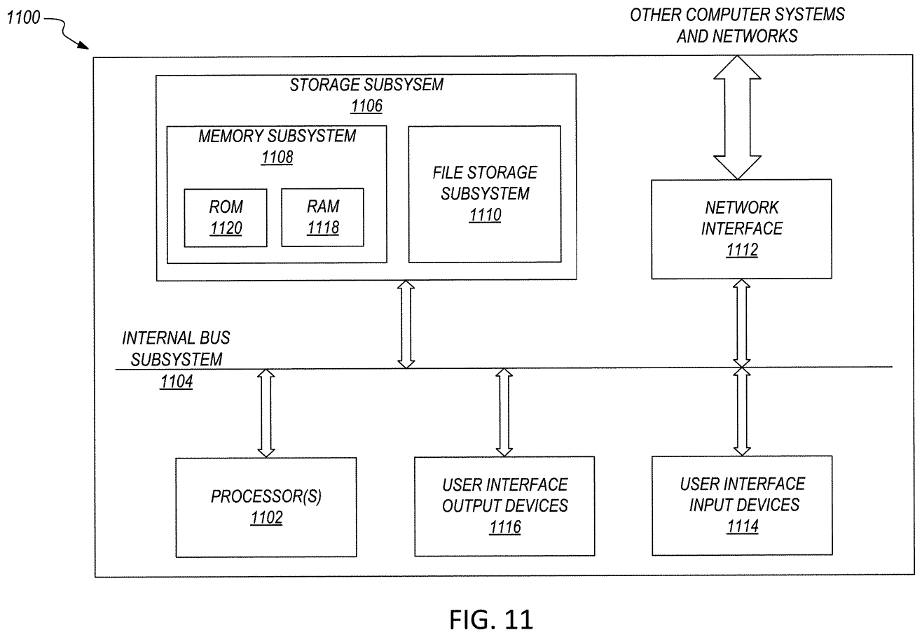

FIG. 11 is a simplified block diagram of computer system 1100 configured to operate aspects of a LiDAR-based detection system, according to certain embodiments. Computer system 1100 can be used to implement any of the systems and modules discussed above with respect to FIGS. 1-6. For example, computer system 1100 may operate aspects of threshold control 1080, TOF module 1034, processor(s) 1020, control system 1040, or any other element of LiDAR system 1000 or other system described herein. Computer system 1100 can include one or more processors 1102 that can communicate with a number of peripheral devices (e.g., input devices) via a bus subsystem 1104. These peripheral devices can include storage subsystem 1106 (comprising memory subsystem 1108 and file storage subsystem 1110), user interface input devices 1114, user interface output devices 1116, and a network interface subsystem 1112.

In some examples, internal bus subsystem 1104 (e.g., CAMBUS) can provide a mechanism for letting the various components and subsystems of computer system 1100 communicate with each other as intended. Although internal bus subsystem 1104 is shown schematically as a single bus, alternative embodiments of the bus subsystem can utilize multiple buses. Additionally, network interface subsystem 1112 can serve as an interface for communicating data between computer system 1100 and other computer systems or networks. Embodiments of network interface subsystem 1112 can include wired interfaces (e.g., Ethernet, CAN, RS232, RS485, etc.) or wireless interfaces (e.g., ZigBee, Wi-Fi, cellular, etc.).

In some cases, user interface input devices 1114 can include a keyboard, pointing devices (e.g., mouse, trackball, touchpad, etc.), a barcode scanner, a touch-screen incorporated into a display, audio input devices (e.g., voice recognition systems, microphones, etc.), Human Machine Interfaces (HMI) and other types of input devices. In general, use of the term “input device” is intended to include all possible types of devices and mechanisms for inputting information into computer system 1100. Additionally, user interface output devices 1116 can include a display subsystem, a printer, or non-visual displays such as audio output devices, etc. The display subsystem can be any known type of display device. In general, use of the term “output device” is intended to include all possible types of devices and mechanisms for outputting information from computer system 1100.

Storage subsystem 1106 can include memory subsystem 1108 and file/disk storage subsystem 1110. Subsystems 1108 and 1110 represent non-transitory computer-readable storage media that can store program code and/or data that provide the functionality of embodiments of the present disclosure. In some embodiments, memory subsystem 1108 can include a number of memories including main random access memory (RAM) 1118 for storage of instructions and data during program execution and read-only memory (ROM) 1120 in which fixed instructions may be stored. File storage subsystem 1110 can provide persistent (i.e., non-volatile) storage for program and data files, and can include a magnetic or solid-state hard disk drive, an optical drive along with associated removable media (e.g., CD-ROM, DVD, Blu-Ray, etc.), a removable flash memory-based drive or card, and/or other types of storage media known in the art.

It should be appreciated that computer system 1100 is illustrative and not intended to limit embodiments of the present disclosure. Many other configurations having more or fewer components than system 1100 are possible.

The various embodiments further can be implemented in a wide variety of operating environments, which in some cases can include one or more user computers, computing devices or processing devices, which can be used to operate any of a number of applications. User or client devices can include any of a number of general purpose personal computers, such as desktop or laptop computers running a standard operating system, as well as cellular, wireless and handheld devices running mobile software and capable of supporting a number of networking and messaging protocols. Such a system also can include a number of workstations running any of a variety of commercially available operating systems and other known applications for purposes such as development and database management. These devices also can include other electronic devices, such as dummy terminals, thin-clients, gaming systems and other devices capable of communicating via a network.

Most embodiments utilize at least one network that would be familiar to those skilled in the art for supporting communications using any of a variety of commercially available protocols, such as TCP/IP, UDP, OSI, FTP, UPnP, NFS, CIFS, and the like. The network can be, for example, a local-area network, a wide-area network, a virtual private network, the Internet, an intranet, an extranet, a public switched telephone network, an infrared network, a wireless network, and any combination thereof.

In embodiments utilizing a network server, the network server can run any of a variety of server or mid-tier applications, including HTTP servers, FTP servers, CGI servers, data servers, Java servers, and business application servers. The server(s) also may be capable of executing programs or scripts in response to requests from user devices, such as by executing one or more applications that may be implemented as one or more scripts or programs written in any programming language, including but not limited to Java®, C, C # or C++, or any scripting language, such as Perl, Python or TCL, as well as combinations thereof. The server(s) may also include database servers, including without limitation those commercially available from Oracle®, Microsoft®, Sybase®, and IBM®.

The environment can include a variety of data stores and other memory and storage media as discussed above. These can reside in a variety of locations, such as on a storage medium local to (and/or resident in) one or more of the computers or remote from any or all of the computers across the network. In a particular set of embodiments, the information may reside in a storage-area network (SAN) familiar to those skilled in the art. Similarly, any necessary files for performing the functions attributed to the computers, servers or other network devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch screen or keypad), and at least one output device (e.g., a display device, printer or speaker). Such a system may also include one or more storage devices, such as disk drives, optical storage devices, and solid-state storage devices such as RAM or ROM, as well as removable media devices, memory cards, flash cards, etc.

Such devices also can include a computer-readable storage media reader, a communications device (e.g., a modem, a network card (wireless or wired), an infrared communication device, etc.), and working memory as described above. The computer-readable storage media reader can be connected with, or configured to receive, a non-transitory computer readable storage medium, representing remote, local, fixed, and/or removable storage devices as well as storage media for temporarily and/or more permanently containing, storing, transmitting, and retrieving computer-readable information. The system and various devices also typically will include a number of software applications, modules, services or other elements located within at least one working memory device, including an operating system and application programs, such as a client application or browser. It should be appreciated that alternate embodiments may have numerous variations from that described above. For example, customized hardware might also be used and/or particular elements might be implemented in hardware, software (including portable software, such as applets) or both. Further, connection to other computing devices such as network input/output devices may be employed.

Non-transitory storage media and computer-readable storage media for containing code, or portions of code, can include any appropriate media known or used in the art such as, but not limited to, volatile and non-volatile, removable and non-removable media implemented in any method or technology for storage of information such as computer-readable instructions, data structures, program modules or other data, including RAM, ROM, Electrically Erasable Programmable Read-Only Memory (EEPROM), flash memory or other memory technology, CD-ROM, DVD or other optical storage, magnetic cassettes, magnetic tape, magnetic disk storage or other magnetic storage devices or any other medium which can be used to store the desired information and which can be accessed by a system device. Based on the disclosure and teachings provided herein, a person of ordinary skill in the art will appreciate other ways and/or methods to implement the various embodiments. However, computer-readable storage media does not include transitory media such as carrier waves or the like.

Other variations are within the spirit of the present disclosure. Thus, while the disclosed techniques are susceptible to various modifications and alternative constructions, certain illustrated examples thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims. For instance, any of the examples, alternative examples, etc., and the concepts thereof may be applied to any other examples described and/or within the spirit and scope of the disclosure.

The use of the terms “a” and “an” and “the” and similar referents in the context of describing the disclosed examples (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate examples of the disclosure and does not pose a limitation on the scope of the disclosure unless otherwise claimed. No language in the specification should be construed as indicating any non-claimed element as essential to the practice of the disclosure.

What is claimed is:

1. A micro-electromechanical system (MEMS) apparatus for beam steering in a Light Detection and Ranging (LiDAR) system of an autonomous vehicle, the apparatus comprising:
a mirror mass having a reflective surface and at least first and second respective sides;
first and second supporting torsion springs, wherein the first and second supporting torsion springs have first ends, respectively, connected to the first and second respective sides of the mirror mass, on opposite sides, to support the mirror mass;
first and second common terminals connected to the first and second supporting torsion springs, respectively, on second ends of the first and second supporting torsion springs;
a plurality of first fingers extending from the mirror mass on first and second sides orthogonal to the first and second supporting torsion springs;
first and second bias terminals opposite the first and second sides of the mirror mass;
a plurality of second fingers extending from the first and second bias terminals, the plurality of second fingers being interleaved with the plurality of first fingers and partially overlapping the plurality of first fingers;
an oxide layer below the first and second common terminals and the first and second bias terminals;
a die substrate below the oxide layer;
a chip package having a chip package substrate;
a die attach layer between the die substrate and the chip package substrate, and adhesively bonded to both the die substrate and the chip package substrate;
wherein the die attach layer is a film having adhesive on both sides;
wherein the die attach layer is between 25-150 μm thick;
wherein the die attach layer has a Young's modulus less than 25,000 psi;
wherein the die substrate is patterned with a plurality of cavities open to the die attach layer; and
wherein the cavities are 25-300 μm deep.

2. The apparatus of claim 1 further comprising:
an array of MEMS mirrors over the die substrate, each having a reflective surface for intercepting a laser beam and redirecting it toward an environment to be detected.

3. The apparatus of claim 1 wherein the plurality of cavities comprise cavities along a perimeter of each of four sides of the die substrate.

4. The apparatus of claim 1 wherein the plurality of cavities comprise a cross pattern.

5. The apparatus of claim 1 wherein the plurality of cavities comprise a plurality of vertical cavities, and a plurality of horizontal crossing cavities, forming a cross-hatched pattern.

6. The apparatus of claim 1 wherein the die attach layer has a Young's modulus between 1,000-15,000 psi.

7. The apparatus of claim 1 wherein the die attach layer is 100 μm thick+−10%.

8. The apparatus of claim 1 wherein the chip package substrate comprises one of alumina or Kovar.

9. A micro-electromechanical system (MEMS) apparatus for beam steering in a Light Detection and Ranging (LiDAR) system of an autonomous vehicle, the apparatus comprising:
a mirror mass having a reflective surface and at least first and second respective sides;
first and second supporting torsion springs, wherein the first and second supporting torsion springs have first ends, respectively, connected to the first and second respective sides of the mirror mass, on opposite sides, to support the mirror mass;
first and second common terminals connected to the first and second supporting torsion springs, respectively, on second ends of the first and second supporting torsion springs;
a plurality of first fingers extending from the mirror mass on first and second sides orthogonal to the first and second supporting torsion springs;
first and second bias terminals opposite the first and second sides of the mirror mass;
a plurality of second fingers extending from the first and second bias terminals, the plurality of second fingers being interleaved with the plurality of first fingers and partially overlapping the plurality of first fingers;
an oxide layer below the first and second common terminals and the first and second bias terminals;
a die substrate below the oxide layer;
a chip package having a chip package substrate;
a die attach layer between the die substrate and the chip package substrate, and adhesively bonded to both the die substrate and the chip package substrate;
wherein the die attach layer has a Young's modulus less than 25,000 psi; and
wherein the die substrate is patterned with a plurality of cavities open to the die attach layer.

10. The apparatus of claim 9 further comprising:
an array of MEMS mirrors over the die substrate, each having a reflective surface for intercepting a laser beam and redirecting it toward an environment to be detected.

11. The apparatus of claim 9 wherein the plurality of cavities comprise a plurality of vertical cavities, and a plurality of horizontal crossing cavities, forming a cross-hatched pattern.

12. The apparatus of claim 9 wherein the die attach layer has a Young's modulus between 1,000-15,000 psi.

13. The apparatus of claim 9 wherein the cavities are 25-300 μm deep.

14. The apparatus of claim 9 wherein the die attach layer is an epoxy.

15. The apparatus of claim 9 wherein the die attach layer is a film having adhesive on both sides.

16. The apparatus of claim 9 wherein the die attach layer between 25-150 μm thick.

17. The apparatus of claim 16 wherein the die attach layer is 100 μm thick+−10%.

18. The apparatus of claim 1 wherein the chip package substrate comprises one of alumina or Kovar.

19. A method for forming a micro-electromechanical system (MEMS) mirror chip, the method comprising:
providing a die substrate;
providing a MEMS mirror structure on the die substrate, the MEMS mirror structure including
a mirror mass having a reflective surface and at least first and second respective sides;
first and second supporting torsion springs, wherein the first and second supporting torsion springs have first ends, respectively, connected to the first and second respective sides of the mirror mass, on opposite sides, to support the mirror mass;
first and second common terminals connected to the first and second supporting torsion springs, respectively, on second ends of the first and second supporting torsion springs;
a plurality of first fingers extending from the mirror mass on first and second sides orthogonal to the first and second supporting torsion springs;
first and second bias terminals opposite the first and second sides of the mirror mass;
a plurality of second fingers extending from the first and second bias terminals, the plurality of second fingers being interleaved with the plurality of first fingers and partially overlapping the plurality of first fingers;
providing a chip package having a chip package substrate;
attaching a die attach layer between the die substrate and the chip package substrate;
adhesively bonding the die attach layer to both the die substrate and the chip package substrate;
wherein the die attach layer has a Young's modulus less than 25,000 psi; and
wherein the die substrate is patterned with a plurality of cavities open to the die attach layer.

20. The method of claim 19 further comprising:
etching a plurality of open cavities in the die substrate opposite the mirror structure to form a pattern;
etching the open cavities to a depth of 25-300 μm; and
choosing a die attach layer with a thickness between 25-150 μm and a Young's modulus between 1,000-15,000 psi.
